(19) United States
(12) Patent Application Publication
(10) Pub. No.: US 2006/0163559 A1
(43) Pub. Date: Jul. 27, 2006

(54) Organic thin film transistor and manufacturing method thereof

(75) Inventors: Akio Koganei, Chiba (JP); Takamitsu Morota, Gunma-ken (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 10/533,088

(22) PCT Filed: Mar. 31, 2004
(86) PCT No.: PCT/JP04/04707

§ 371 Date: Apr. 28, 2005

(30) Foreign Application Priority Data
Mar. 31, 2003 (JP) 2003-096209

(51) Int. Cl. H01L 29/08; H01L 35/24; H01L 51/00

(52) U.S. Cl. 257/40

(57) ABSTRACT

There is provided an organic thin film transistor comprising: an organic substrate; a gate electrode; a gate insulating film; an organic semiconductor film; a source electrode; and a drain electrode, and in the organic thin film transistor, an average surface roughness Ra of the gate electrode which is in contact with the gate insulating film is 0.1 nm to 15 nm. The organic thin film transistor provides a stable performance characteristic even when a conductor film provided on a substrate whose shape is unstable and whose flatness is low as compared with a silicon wafer, such as a substrate made of a glass epoxy resin, is used as a gate electrode.

### TECHNICAL FIELD

The present invention relates to an organic thin film transistor using an organic semiconductor material and a method of manufacturing the organic thin film transistor.

### BACKGROUND ART

In recent years, a development race of a thin film transistor using an organic semiconductor material (hereinafter referred to as “organic thin film transistor”) is accelerating. By using the organic material, a process temperature is reduced. Therefore, it is expected that transistors can be formed on a large area at low cost. It is anticipated that organic thin film transistors will be applied to a drive circuit for a thin display and an electronic paper, a radio frequency identification (RF-ID) tag, an IC card, and the like. There are several technical reviews (see for example, C. D. Dimitrakopoulos, et al. “Organic Thin Film Transistors for Large Area Electronics”, Advanced Material, 2002, 14, No. 2, pp. 99-117).

FIG. 3 shows a structural example of an organic thin film transistor. Reference numeral 301 denotes a substrate; 302, a gate electrode made from a conductor film; 303, a gate insulating film; 304, an organic semiconductor film; 305, a source electrode; and 306, a drain electrode.

In FIG. 3, for example, a glass epoxy resin can be used for the substrate 301. In this case, with respect to the gate electrode 302, the conductor film is patterned in a gate electrode shape and then subjected to a planarization process by polishing. The gate insulating film, the organic semiconductor film, the source electrode, and the drain electrode are formed on the processed conductor film, thereby composing the organic thin film transistor.

In order to operate the organic thin film transistor, a voltage that exceeds a threshold voltage Vth is applied to the gate electrode in a state in which the source electrode is grounded and a drain voltage Vdd is applied to the drain electrode. At this time, a conductivity of the organic thin film transistor is changed by an electric field from the gate electrode, so that a current flows between the source electrode and the drain electrode. Therefore, as in a switch, the on-and-off control of the current flowing between the source electrode and the drain electrode can be performed according to the gate voltage.

Up to now, a large number of examples in which an organic thin film transistor is formed using a substrate made of a material other than an Si wafer have been reported. However, there are few examples in which mobility exceeds 0.1 cm²/Vs. For example, there is a report that mobility exceeds 1 cm²/Vs when a transistor is formed on an Si wafer using pentacene for an organic semiconductor film. However, even if the same pentacene is used, when a transistor is formed on a PET, the maximum mobility is about 0.05 cm²/Vs. There is a report that mobility is 0.2 cm²/Vs when a transistor is formed on a polycarbonate. This is an exceptional case because a high dielectric constant material is used for a gate insulating film (see for example, C. D. Dimitrakopoulos, et al. “Low-Voltage Organic Transistors on Plastic Comprising High-Dielectric Constant Gate Insulators”, Science, 1999, 283, p. 822). It is conceivable that a substrate surface roughness is one of the factors reducing the mobility even in the case of using the same material.

In producing the organic thin film transistor having the structure shown in FIG. 3, the flatness of the surface of the gate electrode is important. In particular, there is a problem in the case where an organic polymer material such as polyethylene terephthalate or polycarbonate having lower flatness than a silicon wafer is used for a substrate, or in the case where a glass epoxy resin to which a copper foil is added is used for a printed substrate. Because the surface roughness is 10 times to 1000 times larger than that of the silicon wafer, a coverage of the gate insulating film formed on the gate electrode is bad at some locations to increase a gate leakage. Therefore, a sufficient electric field effect is not obtained. In addition, a variation in film thickness of the gate insulating film is caused at some locations, so that this becomes a factor varying transistor characteristics. Further, in some cases, the mobility is reduced due to the surface roughness.

When an organic thin film transistor having stable operating characteristics is produced by using a substrate other than the silicon wafer, a process for planarizing the surface of the gate electrode on which the gate insulating film is formed is required. As a planarizing process, there has been widely known chemical mechanical polishing (CMP) for planarizing the insulating film to realize a multi-layer wiring in silicon technology. However, in a method of directly forming a transistor on a substrate whose shape is unstable and whose flatness is low as compared with the silicon wafer, such as a substrate made of a glass epoxy resin, sufficient findings to the surface roughness required on the surface of the gate electrode are not obtained.

### DISCLOSURE OF THE INVENTION

An object of the present invention is to define a planarization level required to obtain a stable transistor operation in the case where a surface of a gate electrode is planarized by a polishing process.

Another object of the present invention is to provide a technique of using as a gate electrode a conductor film provided on a substrate whose shape is unstable and whose flatness is low as compared with a silicon wafer, such as a substrate made of a glass epoxy resin.

Still another object of the present invention is to provide a low cost semiconductor device using a large number of transistors in which stable operating characteristics are obtained.

After concentrated studies were conducted with respect to the present invention, it is concluded that the following structures are suitable.

That is, according to the present invention, there is provided an organic thin film transistor comprising: an organic substrate; a gate electrode; a gate insulating film; an organic semiconductor film; a source electrode; and a drain electrode, in which an average surface roughness Ra of the gate electrode which is in contact with the gate insulating film is 0.1 nm to 15 nm.

It is preferable that the organic substrate is made of one of a glass epoxy resin, polyethylene terephthalate, and polyimide.

Further, according to the present invention, there is provided a method of manufacturing an organic thin film transistor which comprises an organic substrate, a gate electrode, a gate insulating film, an organic semiconductor film, a source electrode, and a drain electrode, the method comprises the steps of: preparing an organic substrate in which a planarized gate electrode is formed on a surface thereof; and forming a gate insulating film on the planarized gate electrode, in which an average surface roughness Ra of the planarized gate electrode is 0.1 nm to 15 nm.

It is preferable that the organic substrate is made of one of a glass epoxy resin, polyethylene terephthalate, and polyimide.

Further, it is preferable that the planarized gate electrode is formed by sputtering, or that the method of manufacturing an organic thin film transistor further includes planarizing the gate electrode.

Further, it is preferable that in planarizing, at least one of chemical mechanical polishing (CMP), soft etching, and polishing tape processing is performed.

According to the present invention, in the organic thin film transistor using the organic semiconductor film, an average surface roughness Ra on the surface of the gate electrode which is in contact with the gate insulating layer is set to a range of 0.1 nm to 15 nm. Therefore, it is possible to use as the gate electrode a conductor film provided on a substrate whose shape is unstable and whose flatness is low as compared with a silicon wafer, such as a substrate made of a glass epoxy resin.

Also, it is possible to obtain a low cost semiconductor device using a large number of transistors in which stable operating characteristics.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1 is a schematic view showing a structure of an organic thin film transistor according to the present invention.

FIG. 2 is an AFM image of a thin film composing a gate electrode used for the organic thin film transistor according to the present invention.

FIG. 3 is a schematic view showing a structure of a conventional organic thin film transistor.

FIG. 4 is a schematic view showing the process of producing the organic thin film transistor according to the present invention.

FIG. 5 is a schematic view showing the process of producing the organic thin film transistor according to the present invention.

FIG. 6 is a schematic view showing the process of producing the organic thin film transistor according to the present invention.

FIG. 7 is a schematic view showing the process of producing the organic thin film transistor according to the present invention.

FIG. 8 is a schematic view showing the process of producing the organic thin film transistor according to the present invention.

FIG. 9 is an AFM image of a thin film composing a gate electrode in a comparative example.

FIG. 10 is a graph showing a measurement result in the case where a substrate (produced by Toray Industries, Inc.) is used and no processing is performed in Example 3 of the present invention.

FIG. 11 is a graph showing a measurement result in the case of soft etching processing in Example 3 of the present invention.

FIG. 12 is a graph showing a measurement result in the case of CMP in Example 3 of the present invention.

FIG. 13 is a graph showing a measurement result in the case of tape processing in Example 3 of the present invention.

FIG. 14 is a graph showing a measurement result in the case of CMP in Example 3 of the present invention.

FIG. 15 is a graph showing a measurement result in Example 4 of the present invention.

FIG. 16 is a graph showing a measurement result on a UPISEL D substrate produced by UBE Industries, Ltd. in Example 4 of the present invention.

FIG. 17 is a graph showing results in Example 3 and Example 4 of the present invention.

### BEST MODES FOR CARRYING OUT THE INVENTION

Preferred embodiments of the present invention will now be described in detail in accordance with the accompanying drawings.

Concentrated studies were conducted with respect to the flatness on a surface of a gate electrode which is suitably used for producing a transistor on a substrate whose shape is unstable and whose flatness is low, such as a substrate made of a glass epoxy resin. From the studies, it has been found effective to set an average surface roughness Ra on the surface of the gate electrode to a range of 0.1 nm to 15 nm. That is, the following is found. Even if the surface roughness before polishing is a level outside the range, if processing is performed such that the surface roughness falls within this range after polishing, sufficient transistor characteristics can be obtained. Alternatively, by preparing a substrate including a flat gate electrode in which the surface roughness falls within the range, the sufficient transistor characteristics can be obtained. The present invention has been made based on the findings.

In the present invention, an average surface roughness Ra is defined by a mean roughness (Ra) described in Digital Instruments NanoScope III, offline menu manual Ver. 4.4.

According to this description, a three-dimensional average roughness with respect to a center plane is defined by the following Expression (1),

$$Ra - \frac{\sum \vert Zi - Zcp \vert}{N} \qquad ( 1 )$$

where N: the number of data points

Zi: value of Z at each of the data point

Zcp: value of Z on center plane.

The center plane indicates a plane which is located such that a volume produced from a region surrounded by the center plane and a surface shape in the front side of the center plane becomes equal to that in the rear side thereof which is opposed to the front side.

The JIS of a roughness estimation index to a three-dimensional surface form is not provided like in the case of a two-dimensional surface form. Even in the case of a surface shape observing apparatus using a white interferometer (Zygo product or the like) or a surface shape observing apparatus using laser light, an index written by Ra is proposed from various companies. There is no situation that the indexes Ra obtained by measuring the same surface of the same sample using different measurement units are always identical. However, even when a measurement method is changed, substantially identical numerical values are obtained, so that a function in the case where Ra is used as an index is satisfied. In addition, the index is compatible with an arithmetic average roughness Ra defined by JIS B-0601.

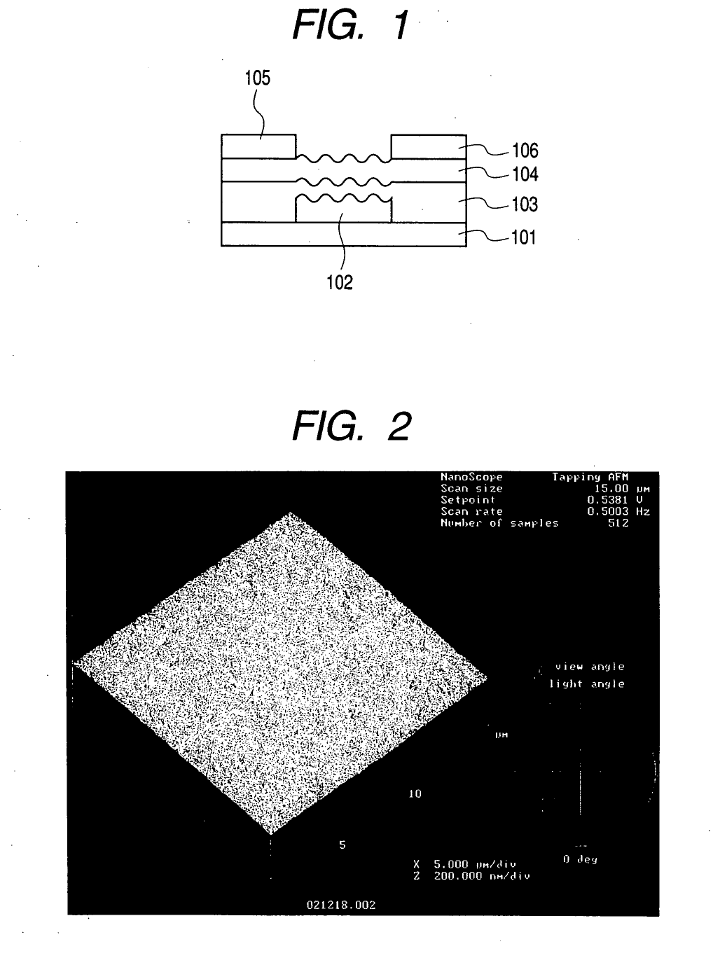

FIG. 1 shows a structural example of an organic thin film transistor according to the present invention. Reference numeral 101 denotes a substrate; 102, a gate electrode made from a conductor film; 103, a gate insulating film; 104, an organic semiconductor film; 105, a source electrode; and 106, a drain electrode.

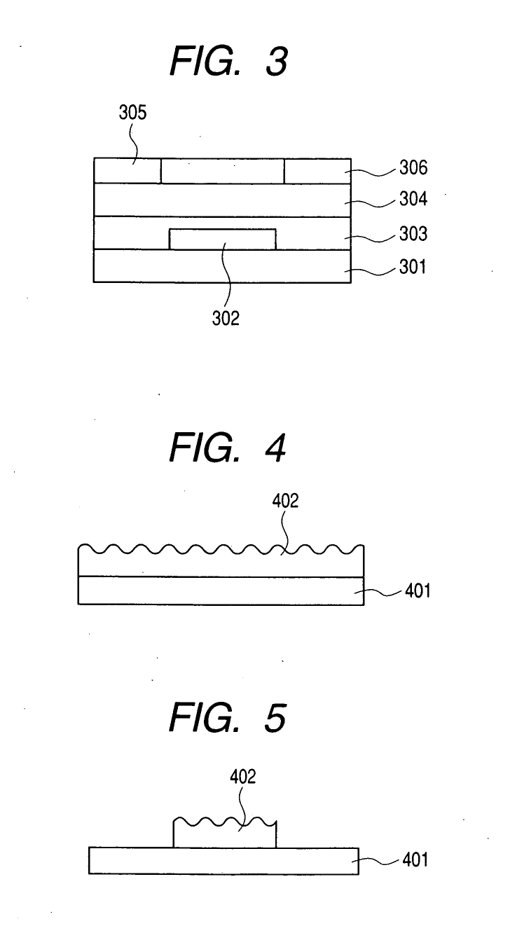

As compared with FIG. 3, FIG. 1 according to the embodiment of the present invention emphasizes a state in which the surface roughnesses of the gate electrode, the gate insulating film, and the organic semiconductor film in a channel region located between the source electrode and the drain electrode are large. A polishing condition of the gate electrode is appropriately set to define a necessary flatness level. Therefore, it is possible to produce an organic thin film transistor using a low cost substrate.

The operational order of the organic thin film transistor according to the present invention is the same as in the conventional transistor shown in FIG. 3. That is, a voltage that exceeds a threshold voltage Vth is applied to the gate electrode in a state in which the source electrode is grounded and a drain voltage Vdd is applied to the drain electrode. At this time, the conductivity of the organic thin film transistor is changed by an electric field from the gate electrode, so that a current flows between the source electrode and the drain electrode. Therefore, as in a switch, the on-and-off control of the current flowing between the source electrode and the drain electrode can be performed according to the gate voltage.

The surface roughness of a copper foil bonded to the glass epoxy resin substrate on which polishing is not performed is about 1 μm. The average surface roughness Ra of the copper foil falls within a range of 0.1 nm to 15 nm by a CPM, thereby obtaining sufficient characteristics. It is possible to reduce Ra to a value smaller than 0.1 nm. However, this reduction targets a surface roughness superior to that of the silicon wafer. Therefore, polishing requires a lot of time, so that the merit in the case where the glass epoxy resin substrate is used is lost in cost. In addition, it is necessary to increase a film thickness of the conductor film before polishing. On the other hand, when the organic thin film transistor is produced in a state in which Ra exceeds 15 nm, a gate leakage is frequently caused, thereby impairing the reliability. In addition, the mobility cannot be increased. Therefore, when an organic thin film transistor is formed using a substrate other than a silicon wafer, it is desirable that the average surface roughness Ra specified by the embodiment of the present invention is set to a range of 0.1 nm to 15 nm. Further, to increase the merit in terms of cost, it is desirable that the average surface roughness Ra is set to a range of 1 nm to 10 nm. When the reliability is further improved to obtain the merit in terms of cost, it is most desirable that the average surface roughness Ra is set to a range of 1 nm to 5 nm.

An organic substrate according to the embodiment of the present invention can be selected from a substrate made of a polymer material such as polyethylene terephthalate, polycarbonate, polyethylene, polystyrene, polyimide, polyvinyl acetate, polyvinyl chloride, or polyvinylidene chloride, a glass epoxy resin substrate used for a printed circuit board, and the like. It is possible to suitably select a substrate according to usage from the viewpoint of items required for the substrate, such as flatness, strength, heat resistance, thermal expansion coefficient, and cost.

A material of the organic semiconductor film according to the embodiment of the present invention can be selected as appropriate from an oligomer having a n conjugated electron, such as pentacene, tetracene, or anthracene, an organic semiconductor polymer such as polythiophene, polyacene, polyacetylene, or polyaniline.

An inorganic oxide such as SiO₂, Al₂O₃, or Ta₂O₅, or a nitride such as Si₃N₄ can be used for the gate insulating film according to the embodiment of the present invention. When an on-resistance is reduced to increase a drain current, it is preferable that the gate insulating film is made of a high dielectric constant material. In addition, an insulating organic polymer such as polyvinylphenol (PVP), polymethyl methacrylate (PMMA), or polyethylene can be used.

A noble metal such as gold, silver, or platinum, or a high conductivity material such as copper or aluminum can be used for the gate electrode, the source electrode, and the drain electrode according to the embodiment of the present invention. In addition, these electrodes can be formed using a conductive polymer.

The essence of the present invention is to define the surface roughness on the surface of the gate insulating film which is in contact with the organic semiconductor film, which is required to stably operate the organic thin film transistor. Therefore, needless to say, it is possible to technically arrange a polishing method, which can be made by various engineers in the field. An object to be polished may be the gate insulating film, the gate electrode, or the substrate. A state of the surface of the gate insulating film, which is in contact with the organic semiconductor film is absolutely important. However, when the gate insulating film is polished, the thickness of the gate insulating film changes according to locations. Therefore, the conditions of an electric field change or the insulation property is impaired. Thus, according to a most preferable aspect, the gate electrode becomes a polishing object.

Hereinafter, the present invention will be specifically described by giving examples.

### EXAMPLE 1

FIGS. 4 to 8 are schematic views showing a method of producing the organic thin film transistor according to the present invention. In FIG. 4, reference numeral 401 denotes a substrate and 402 denotes a conductor film. With respect to the substrate 401 and the conductor film 402, for example, a glass epoxy resin substrate which is integrally formed with a copper foil is commercially available as a printed circuit board. In this example, a substrate having a thickness of 0.2 mm in which a film thickness of the copper foil serving as the conductor film was 35 μm was used (produced by Hitachi Chemical Co., Ltd.; type: FR-4). A large number of substrates, each of which had a structure in which the conductor film was provided on both surfaces of the substrate. However, the conductor film provided on one surface is unnecessary on the description of the present invention and thus omitted here. The same reference numerals in FIGS. 4 to 8 indicate the same members.

Next, the conductor film was patterned to process it in a desirable gate shape. For this processing, it is possible to perform a mask formation by a lithography technique using a dry film and a shape transfer by wet etching on the conductor film. FIG. 5 shows a state in which the conductor film has been processed in a wiring shape. Reference numeral 402 denotes a conductor film which becomes the gate electrode. After wet etching, the conductor film 402 was polished by a CMP to adjust to a surface roughness required to embody the present invention.

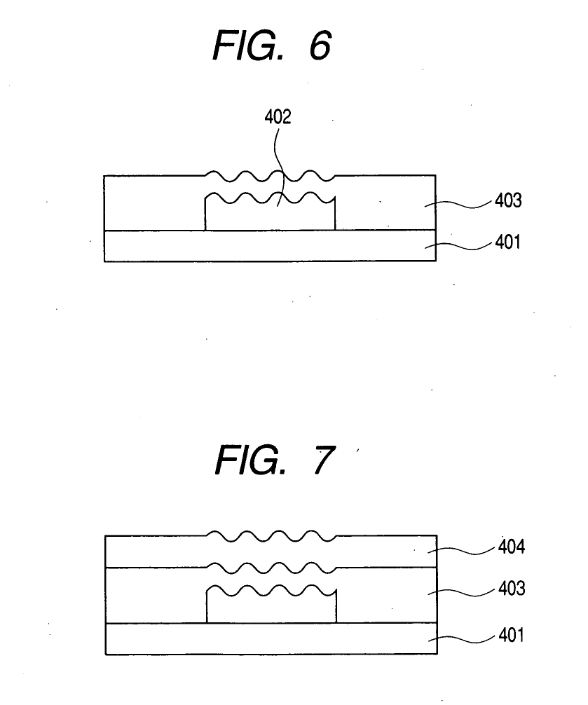

FIG. 6 shows a state in which a gate insulating film 403 was formed on the conductor film 402 which becomes the gate electrode. The gate insulating film 403 was formed using magnetron sputtering system. A film formation region of the gate insulating film 403 was specified by a shadow mask. A sputtering material was Al₂O₃. A film thickness of the gate insulating film 403 was 250 nm.

FIG. 7 shows a state in which an organic semiconductor film 404 was formed on the gate insulating film 403. The organic semiconductor film 404 was formed using evaporation. A film formation region of the organic semiconductor film 404 was specified by a shadow mask. An evaporation material was pentacene refined by sublimation. A film thickness of the organic semiconductor film 404 was 150 nm.

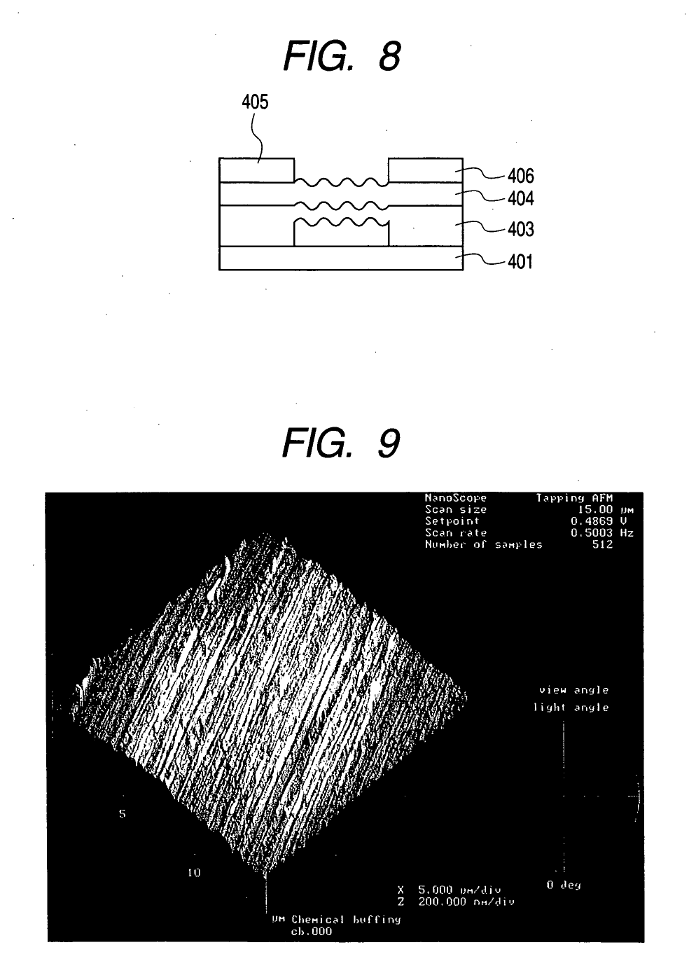

FIG. 8 shows a state in which a source electrode 405 and a drain electrode 406 were provided so as to be in contact with the organic semiconductor film 404. The source electrode 405 and the drain electrode 406 were formed using evaporation. Film formation regions of the source electrode 405 and the drain electrode 406 were specified by a shadow mask. An evaporation material was Au. A film thickness of each of the source electrode 405 and the drain electrode 406 was 100 nm.

The polishing condition was changed to produce substrates having different surface roughnesses Ra on the gate electrode. The substrate which was processed up to the polishing step shown in FIG. 5 was cut to a card size (86 mm×54 mm). The surface roughness on the gate electrode was evaluated by a scanning probe microscope (SPM) (produced by Digital Instruments Inc.; product name: DI5000). The measurement was performed on five points within an area of 15 μm square in a tapping mode using a high aspect type probe tip AR5 (tip curvature radius was 10 nm to 15 nm and probe length was 2 μm). FIG. 2 shows an example of the surface roughness specified by the present invention, in which Ra is 3.8 nm. FIG. 2 is an atomic force microscope (AFM; scanning size: 15 μm) image on the surface of the gate electrode. After the AFM measurement, steps that follow the step shown in FIG. 6 were performed on the substrate to complete a transistor device. After the completion, A DC characteristic of the transistor device was measured by a semiconductor parameter analyzer (HP4155B). With respect to a pattern shape used for the test, 120 transistor devices each having the same size were arranged on a single substrate to be cut. As a result, a preferable transistor characteristic in which a gate leakage was small and a variation in Vth was small was obtained.

On the other hand, FIG. 9 shows a comparative example to the present invention, in which the surface roughness Ra is 16.7 nm. FIG. 9 is an atomic force microscope (AFM; scanning size: 15 μm) image on the surface of the gate electrode in the comparative example. Similarly to the example, the transistor characteristic was evaluated after the AFM measurement. As a result, it was observed that the gate leakage exceeds an allowable range in a large number of transistor devices.

With respect to transistor performance indexes, there are an on/off ratio which is a ratio between a drain current Ion flowing when a switch is in an on state and a drain current Ioff flowing when a switch is in an off state (Ion/Ioff), a gate leakage indicating the insulation property of the gate insulating film, a cutoff frequency that follows pulse drive, and the like. In this example, whether or not a transistor device whose gate length was 50 μm and gate width was 3 mm has a good quality was determined based on the following reference values.

(Evaluation Conditions)

On/off ratio: the on/off ratio was calculated by comparing drain currents flowing when a gate voltage was changed between −20 V (on state) and O V (off state) in a state in which a source voltage was 0 V and a drain voltage was −20 V, and the transistor device was regarded as a defective product in the case where the calculated on/off ratio was smaller than 500.

Gate leakage: in a state in which the gate voltage was 0 V, the source voltage was 0 V, and the drain voltage was −20 V, the transistor device was regarded as a good quality product in the case where a gate current was equal to or smaller than 1 μA and transistor device was regarded as a defective product in the case where the gate current was larger than 1 μA.

Table 1 shows an experimental result of an incidence of defective products, which was obtained using the above-mentioned evaluation method. As is apparent from Table 1, in the case of a sample in which the average surface roughness Ra specified by the present invention fell within a range of 0.1 nm to 15 nm, the incidence of defective products could be suppressed.

TABLE 1

| Average surface | Incidence of defective |
|---|---|
| roughness Ra | product (%) |
| 0.1 to 1 nm | 3 |
| 1 to 5 nm | 5 |
| 5 to 10 nm | 4 |
| 10 to 15 nm | 10 |
| 15 to 20 nm | 25 |

### EXAMPLE 2

An organic thin film transistor was produced as in Example 1 except that polyethylene terephthalate (PET) was used for the substrate and gold was used for the gate electrode. With respect to the organic thin film transistor, a correlation between the average surface roughness Ra on the surface of the gate electrode and the incidence of defective products was examined.

The used PET was an OHP film whose thickness was 0.1 mm and size was A4. This was cut to a card side (86 mm×54 mm) as in Example 1.

A gold thin film which was to become the gate electrode was formed using a mask by resistance heating of tungsten boat in a vacuum evaporation system. In order to improve the contact of the gold thin film to the substrate, a thin chromium film was formed as a base layer. A thickness of the gold thin film was 0.5 μm and a thickness of the chromium film was 0.1 μm.

Next, a laminate of the chromium film and the gold thin film which was to become the gate electrode was polished by using a CMP. Samples in which the surface roughnesses were different from each other were prepared by adjusting the polishing condition. The remaining steps were performed as in Example 1 to produce the thin film transistor device. A static characteristic of the produced device was measured by a semiconductor parameter analyzer. Table 2 shows a correlation between the average surface roughness Ra and the incidence of defective products of the organic thin film transistor. As is apparent from Table 2, in the case of a sample in which the average surface roughness Ra specified by the present invention fell within a range of 0.1 nm to 15 nm, the incidence of defective products could be suppressed.

TABLE 2

| Average surface | Incidence of defective |
|---|---|
| roughness Ra | product (%) |
| 0.1 to 1 nm | 5 |
| 1 to 5 nm | 2 |
| 5 to 10 nm | 8 |
| 10 to 15 nm | 11 |
| 15 to 20 nm | 31 |

When the organic thin film transistor was used for an integrated circuit in which a large number of transistors were formed, the incidence of defective products which was obtained in Example 1 and Example 2 was not necessarily a sufficient level. This is probably because incidence of defective products is due not only to the above-mentioned gate leakage but also to an experimental defect. Therefore, a difference between the case where the average surface roughness Ra exceeds 15 nm and the case where it is equal to or smaller than 15 nm is seen as a clear significant difference.

### EXAMPLE 3

A polyimide substrate having a thickness of 25 μm was used as the organic substrate. A copper foil having a thickness of 25 μm was grown on the substrate by plating. Four substrates each having the grown copper foil were prepared.

The four substrates were subjected to four types of surface processings, which were no polishing, soft etching processing, polishing tape processing, and CMP processing.

The conditions of the respective surface processing were as follows.

(Processing Conditions)

Soft etching processing: the substrate was immersed in 5% sulfuric acid for 30 seconds and then washed using flowing deionized water for 2 minutes. Tape processing: polishing tape (type: K8000); 60 second in polishing time; 1 m/30 seconds in tape feed speed; and 2 kgf/cm² in roll pressure. CMP processing: Shibaura slurry CHS-3000EM; 5 kg in cylinder pressure; 80 rpm in the number of revolutions of retainer and platen; and 25 minutes in polishing time.

The respective substrates on which the above-mentioned processings were performed were cut to a size of 17 mm square. Then, a correlation between the average surface roughness Ra on the surface of the copper foil and the insulation property of the insulating film formed on the surface thereof was measured. NewView 5032 which was produced by Zygo Corporation was used for the measurement of the average surface roughness Ra. An objective lens of 10× magnification, of a Mirau optical system was used for the measurement. A scan length was set to 5 μm bipolar. A measurement area size was 0.7 mm×0.53 mm.

The substrate which was measured was subjected to ultrasonic cleaning using deionized water for 1 minute and acetone for 1 minute. After the cleaning, an Al₂O₃ film which was to become the gate insulating film was formed on the substrate by a magnetron sputtering apparatus. The film formation was performed by reactive sputtering in a mixture atmosphere containing an Ar gas and an oxygen gas. A film formation pressure was set to 0.5 Pa, applied power was set to 500 W at 13.56 MHz, and a film thickness was set to 370 nm.

After the film formation, a gold film was formed as an upper electrode on the substrate by evaporation using a mask. The mask was made of a chromium film having a thickness of 40 μm, and 100 apertures, each of which had 200 μm square were arranged in the mask at a pitch of 400 μm. A film thickness of the gold film was set to 120 nm.

With respect to each of the samples prepared through the above-mentioned processings, an insulation characteristic between the copper foil and an isolated gold pattern having 200 μm square was measured by a semiconductor parameter analyzer (HP4155B) produced by Hewlett-Packard Development Company.

A leak current value caused at a time when a voltage of 0 V to 40 V was applied between Cu and Au was measured. When a value obtained by dividing a measurement value by an electrode area (current density) exceeded a preset value (1E-8 A/cm²) before the applied voltage reached 40 V, the pattern was determined to be NG and the number of NG patterns were counted. The number of NG patterns was divided by the full number of patterns to calculate an NG percentage (%).

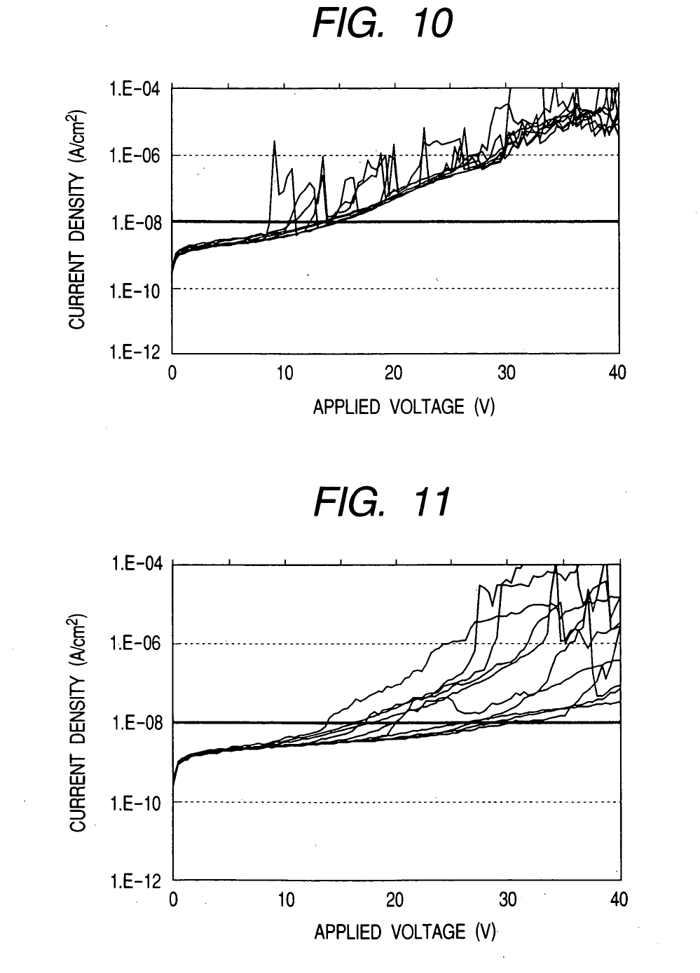

FIG. 10 is a graph showing a measurement result in the case of no polishing. Each line in the graph indicates the insulation characteristic between the gold pattern and the copper foil. Measurement result values obtained at arbitrary 10 points are overlapped with one another on the graph. As a result, Ra was 197 nm, the NG percentage was 100%, and an average current density at 40 V was 5.0×10⁻⁵ A/cm².

Similarly, FIG. 11 is a graph showing a measurement result in the case of soft etching processing. Ra was 163 nm, the NG percentage was 85%, and an average current density at 40 V was 1.9×10⁻⁵ A/cm².

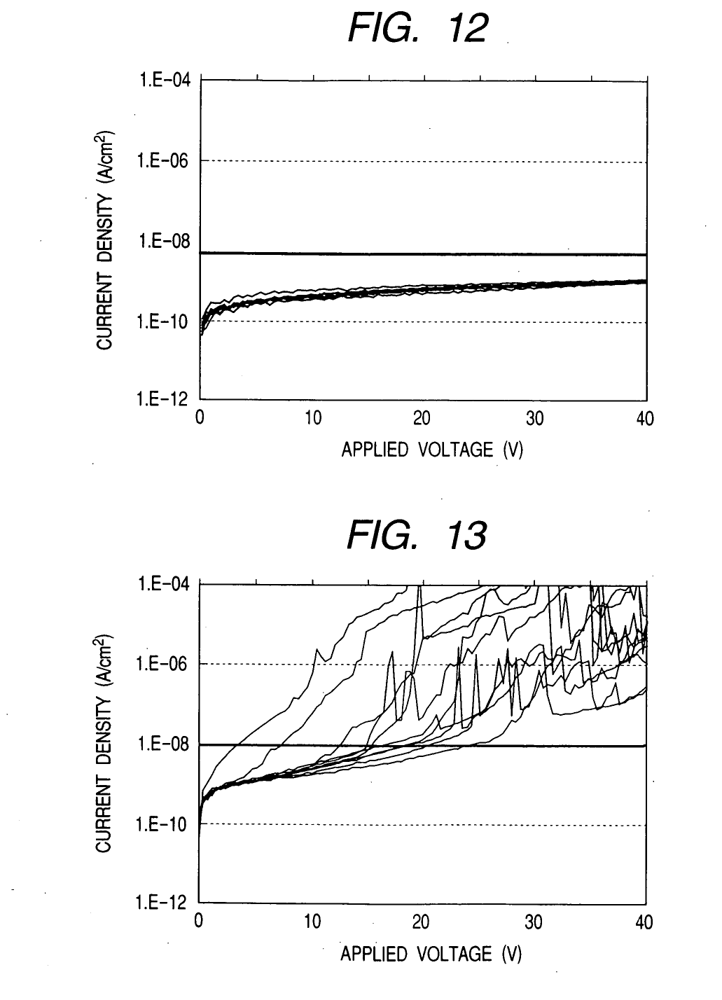

Similarly, FIG. 12 is a graph showing a measurement result in the case of CMP polishing. Ra was 2 nm, the NG percentage was 6.8%, and an average current density at 40 V was 4.0×10⁻⁷ A/cm².

Similarly, FIG. 13 is a graph showing a measurement result in the case of tape processing. Ra was 20 nm, the NG percentage was 100%, and an average current density at 40 V was 9.5×10⁻⁶ A/cm².

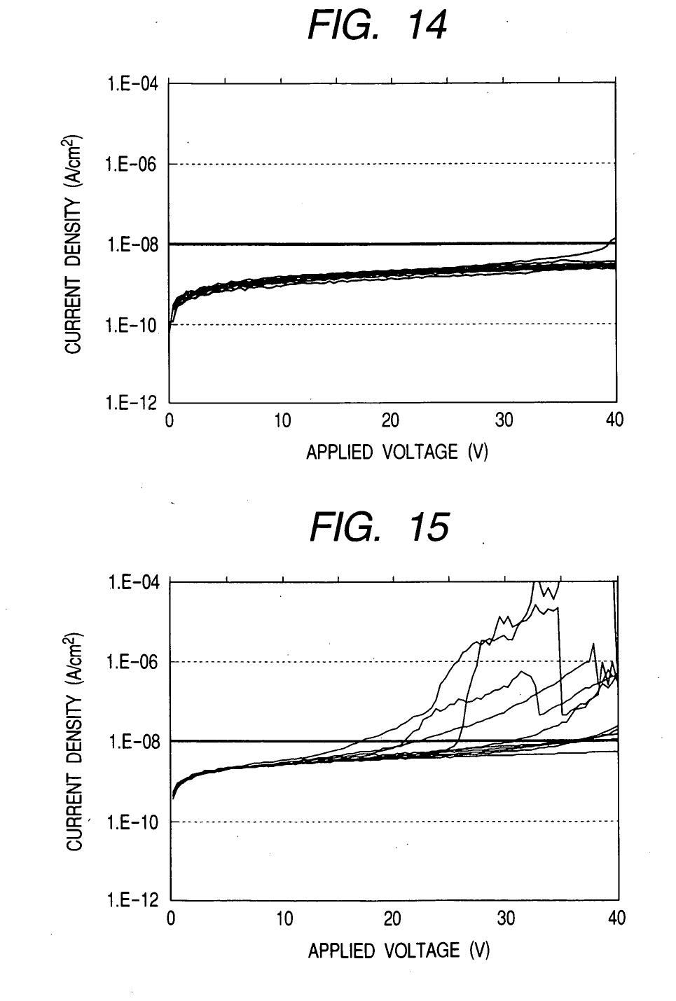

Similarly, FIG. 14 is a graph showing a measurement result in the case of CMP polishing. Ra was 2 nm, the NG percentage was 2.2%, and an average current density at 40 V was 2.2×10⁻⁸ A/cm².

As is apparent from the above-mentioned results, the NG percentage is 85% or more in the case of the sample in which Ra was equal to or larger than 20 nm, but the NG percentage could be suppressed to be smaller than 6.8% in the case of the CMP sample in which Ra is 2 nm.

### EXAMPLE 4

Two different types of polyimide substrates each having a film thickness of 25 μm were prepared as the organic substrates. With respect to the two types of used substrates, one was an A-substrate (produced by Toyo Metallizing Co., Ltd.; product name: Metaloyal FPC) and the other was a B-substrate (produced by UBE Industries, Ltd.; product name: UPISEL D).

A copper foil having a thickness of 0.3 μm was grown on each of the substrates by sputtering.

The above-mentioned respective substrates were cut to a size of 17 mm square. Then, the measurement of the surface roughness was performed. NewView 5032 produced by Zygo Corporation was used for the measurement of the surface roughness. An objective lens of 10× magnification, of a Mirau optical system was used for the measurement. A scan length was set to 5 μm bipolar. A measurement area size was 0.7 mm×0.53 mm.

The substrate which was measured was subjected to ultrasonic cleaning using deionized water for 1 minute and acetone for 1 minute. After the cleaning, an Al₂O₃ film which was to become the gate insulating film was formed by the same process described in Example 3.

After the film formation, as in Example 3, a gold film was formed on the substrate by evaporation using a mask. The mask was made of a chromium film having a thickness of 40 μm, and 100 apertures, each of which has 200 μm square, were arranged in the mask at a pitch of 400 μm. A film thickness of the gold film was set to 120 nm.

With respect to each of the samples of the A- and B-substrates which were prepared through the above-mentioned processings, an insulation characteristic between the copper foil and an isolated gold pattern having 200 μm square was measured by a semiconductor parameter analyzer (HP4155B).

A leak current value caused at a time when a voltage of 0 V to 40 V was applied between Cu and Au was measured. When a value obtained by dividing a measurement value by an electrode area (current density) exceeded a preset value (1E-8 A/cm²) before the applied voltage reached 40 V, the pattern was regarded as NG and the number of NG patterns was counted. The NG percentage was calculated as in Example 3.

FIG. 15 is a graph showing a measurement result on the A-substrate. Ra was 20 nm, the NG percentage was 80%, and an average current density at 40 V was 2.0×10⁻⁷ A/cm².

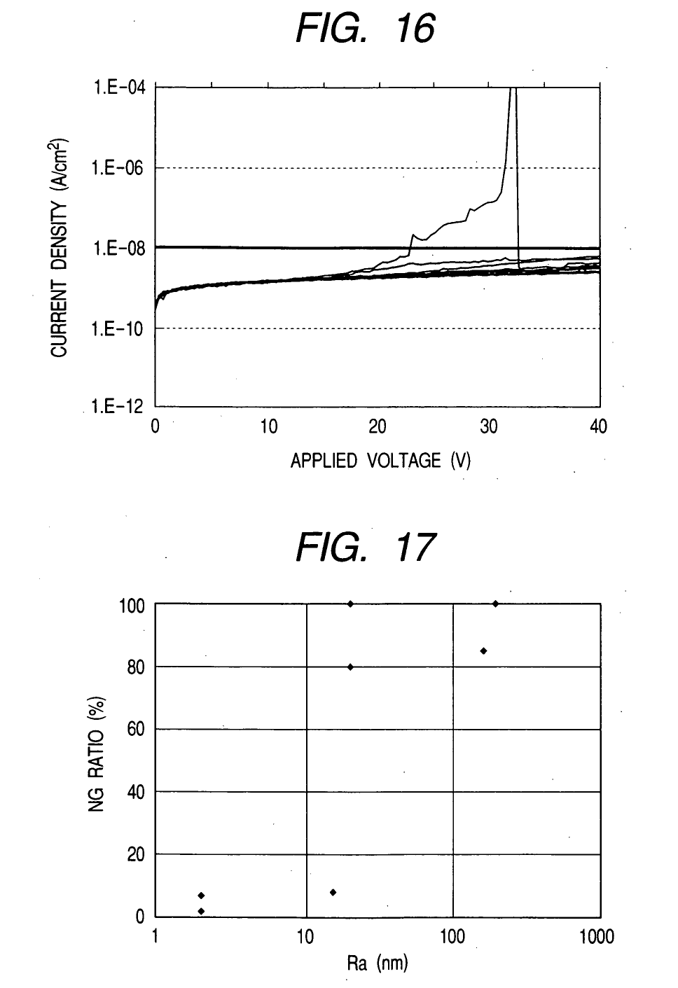

FIG. 16 is a graph showing a measurement result on the B-substrate. Ra was 15 nm, the NG percentage was 8%, and an average current density at 40 V was 1.1×10⁻⁸ A/cm².

As is apparent from the above-mentioned results, the NG percentage was 80% or more in the case of the A-substrate in which Ra was equal to or larger than 20 nm but the NG percentage could be suppressed to be smaller than 8% in the case of the B-substrate in which Ra was 15 nm.

(Evaluation)

FIG. 17 is a graph showing a summary of the results in Example 3 and Example 4. The abscissa indicates the average surface roughness Ra and the ordinate indicates the NG percentage. As is apparent from FIG. 17, when the average surface roughness Ra exceeds 15 nm, the NG percentage tends to significantly increase. It has been found that the range of the average surface roughness Ra (0.1 nm≦Ra≦15 nm) which was regarded as effective by the present invention could be also applied to the substrate on which no polishing was performed. The gate leakage could be reduced, so that a yield in the case where the organic thin film transistor was produced could be improved.

(Production of Thin Film Transistor)

The thin film transistor was produced using the polyimide B-substrate (UPISEL D) in which the average surface roughness Ra was 15 nm. Almina having a thickness of 370 nm as in Example 3 was used for the gate insulating film. The organic semiconductor film was made of pentacene. The source electrode and the drain electrode in the bottom structure were made of a gold film having a film thickness of 500 nm. In an element having a gate length of 50 μm and a gate width of 3 mm, a preferable characteristic such as the mobility of 0.15 cm²/Vs could be obtained under a condition in which a drain voltage was −20 V and a gate voltage was −20 V.

The present invention has been described based on the structure shown in FIG. 1. However, the application of the present invention is not limited to this structure. It can be easily understood by the person skilled in the art that the present invention can be widely applied to a case that faces the same problem. In addition, it can be easily understood by the person skilled in the art that parts which are not directly related to the present invention, such as a field insulating film, a protective film, and contact & via are significantly omitted in the description.

The present invention is not limited to the above embodiments and various changes and modifications can be made within the spirit and scope of the present invention. Therefore to apprise the public of the scope of the present invention, the following claims are made.

1. An organic thin film transistor comprising:
an organic substrate;
a gate electrode;
a gate insulating film;
an organic semiconductor film;
a source electrode; and
a drain electrode,
wherein an average surface roughness Ra of the gate electrode which is in contact with the gate insulating film is 0.1 nm to 15 nm.

2. The organic thin film transistor according to claim 1, wherein the organic substrate is made of one of a glass epoxy resin and polyethylene terephthalate.

3. The organic thin film transistor according to claim 1, wherein the organic substrate is made of polyimide.

4. A method of manufacturing an organic thin film transistor comprising an organic substrate, a gate electrode, a gate insulating film, an organic semiconductor film, a source electrode, and a drain electrode, the method comprising the step of:
preparing an organic substrate in which a planarized gate electrode is formed on a surface thereof; and
forming a gate insulating film on the planarized gate electrode,
wherein an average surface roughness Ra of the planarized gate electrode is 0.1 nm to 15 nm.

5. The method of manufacturing an organic thin film transistor according to claim 4, wherein the organic substrate is made of one of a glass epoxy resin and polyethylene terephthalate.

6. The method of manufacturing an organic thin film transistor according to claim 4, wherein the organic substrate is made of polyimide.

7. The method of manufacturing an organic thin film transistor according to claim 4, wherein the planarized gate electrode is formed by sputtering.

8. The method of manufacturing an organic thin film transistor according to claim 4, further comprising planarizing the gate electrode.

9. The method of manufacturing an organic thin film transistor according to claim 8, wherein in planarizing, at least one of chemical mechanical polishing (CMP), soft etching, and polishing tape processing is performed.
